(19) United States
(12) Patent Application Publication
(10) Pub. No.: US 2004/0140571 A1
(43) Pub. Date: Jul. 22, 2004

(54) Mounting structure of electronic device

(75) Inventors: Yoshihiro Tomura, Osaka (JP); Hiroshi Sogou, Hyogo (JP)

Correspondence Address: McDERMOTT, WILL & EMERY, 600 13th Street, N.W., Washington, DC, 20005-3096, US

(73) Assignee: MATSUSHITA ELECTRIC INDUSTRIAL CO., LTD.

(21) Appl. No.: 10/751,906

(22) Filed: Jan. 7, 2004

(30) Foreign Application Priority Data
Jan. 17, 2003 (JP) P2003-009527

(51) Int. Cl. H01L 23/48

(52) U.S. Cl. 257/778

(57) ABSTRACT

A circuit substrate comprises a terminal electrode having minute dents on its mounting surface, and a conductive adhesive provided on the surface of the terminal electrode. The conductive adhesive comprises conductive particles each having sizes so as to get in the minute dent. Thus, an electrical contact or a bonding area between the circuit substrate and the mounting device is enlarged and then connection reliability in a mount body of an electronic device is improved.

### FIELD OF THE INVENTION

The present invention relates to a mounting structure of a circuit substrate, a semiconductor device using the circuit substrate and an electronic device.

### BACKGROUND OF THE INVENTION

High-density mounting of a semiconductor device on a circuit substrate has been developed as an electronic device is miniaturized and thinned. Accordingly, the number of wirings for connecting the semiconductor device on the circuit substrate is increased, a distance between the wirings is reduced and a width of the wiring is considerably narrowed. Thus, technique for mounting the semiconductor device on the circuit substrate with high precision and high reliability has increasingly become important.

### SUMMARY OF THE INVENTION

A circuit substrate according to the present invention comprises a terminal electrode provided on a mounted surface of the substrate and having minute dents on its surface, and a conductive adhesive provided on a surface of the terminal electrode and having conductive particles, in which the minute dents are filled with the conductive adhesive, and the conductive particles get into the minute dent.

Thus, a part or the whole of the minute dent is filled with the conductive material (conductive particles). In this state, when a mounting device such as the semiconductor device is mounted on the circuit substrate, an area (a contact area) between the circuit substrate and the mounting device can be sufficiently secured. As a result, the mounting device can be surely electrically connected to the circuit substrate. In addition, since the conductive adhesive is provided on the surface of the terminal electrode, stress generated between the circuit substrate and the mounting device can be released.

The present invention is effective in a minimal wiring width of the terminal electrode such as 15 μm or less.

The present invention is surely effective when surface roughness of the terminal electrode on which minute dents are formed is 1.0 μm to 1.5 μm in terms of a ten point average height.

In order to be able to get in the minute dent, an average particle diameter of the conductive particle is preferably 1 nm to 300 nm.

In addition, after the surface of the terminal electrode is covered with the conductive adhesive, the surface of the conductive adhesive may be smoothed. As a concrete example of the smooth surface of the conductive adhesive in this case, there is a smooth surface of 1 nm to 300 nm in terms of a ten point average height. In this constitution also, a contact area between the mounting device and the conductive adhesive is increased. As a result, the mounting device can be surely electrically connected to the circuit substrate.

When the minute dent is filled with the conductive adhesive, it is preferable that the surface of the terminal electrode become the smooth surface of 1 nm to 300 nm in terms of a ten point average height. Thus, the surface of the terminal electrode is constituted to be a smooth surface by selectively filling the minute dent with the conductive adhesive. In this constitution also, a contact area between the mounting device and the circuit substrate through the conductive adhesive is increased. As a result, the mounting device can be surely electrically connected to the circuit substrate.

In addition, it is preferable that the conductive adhesive comprise a resin binder formed of one of an ultraviolet cure resin, thermoplastic resin and thermosetting resin, and the conductive particles engage in the surface of the minute dents when the resin binder shrinks at the time of curing or drying. Thus, the conductive particles are further surely electrically connected to the terminal electrode. In addition, since the conductive particles engage in the surface of the minute dents, a connection distance between the mounting device and the circuit substrate through the conductive adhesive is reduced. As a result, the connection reliability between the circuit substrate and the mounting device can be further improved.

Furthermore, according to a concrete mounting structure using the circuit substrate of the present invention, in a mount body of a semiconductor device in which the semiconductor device is mounted face down on the circuit substrate, a terminal electrode of the semiconductor device comes in contact with the terminal electrode of the circuit substrate and both terminal electrodes are electrically connected.

Similarly, according to a concrete mounting structure using the circuit substrate of the present invention, in a mount body of a semiconductor device in which the semiconductor device is mounted face up on the circuit substrate, the terminal electrode of the circuit substrate and a terminal electrode of the semiconductor device are electrically connected through a connection wire.

Similarly, according to a concrete mounting structure using the circuit substrate of the present invention, in a mount body of a semiconductor device in which an electronic device is mounted on the circuit substrate through a conductive adhesive, the terminal electrode of the circuit substrate and a terminal electrode of the electronic device are electrically connected through the conductive adhesive.

According to the above described concrete mounting structures, an electrical contact or connection area between the circuit substrate and the mounting device is increased. In addition, since the terminal electrode of the circuit substrate and the terminal electrode of the mounting device engage in the conductive particles, further preferable electrical connection can be provided. Furthermore, since the conductive adhesive is provided on the surface of the terminal electrode, stress generated between the circuit substrate and the mounting device can be released. Consequently, electrical characteristics (characteristics of connection resistance and frequency) of an electrical structure comprising the circuit substrate and the mounting device can be improved.

### BRIEF DESCRIPTION OF THE DRAWINGS

Other objects of the present invention become more apparent from the following detailed description of the invention and clearly specified in the appended claims. Implementing the present invention reminds those skilled in the art of many advantages which are not described in this specification.

FIG. 1 is a schematic sectional view showing a circuit substrate according to an embodiment 1 of the present invention;

FIG. 2 is a schematic sectional view showing a circuit substrate of a variation of the embodiment 1;

FIG. 3 is a schematic sectional view showing a circuit substrate of another variation of the embodiment 1;

FIG. 4 is a view showing a constitution of chain-shaped conductive particles;

FIG. 5 is a schematic sectional view showing a mount body of a semiconductor device according to an embodiment 2;

FIG. 6A is a view showing a first constitution of a substantial part of the embodiment 2;

FIG. 6B is a view showing a second constitution of a substantial part of the embodiment 2;

FIG. 6C is a view showing a third constitution of a substantial part of the embodiment 2;

FIG. 7 is a schematic sectional view showing a mount body of a semiconductor device according to an embodiment 3 of the present invention;

FIG. 8 is a schematic sectional view showing a mount body of an electronic device according to an embodiment 4 of the present invention;

FIG. 9 is a schematic sectional view showing a mount body of a semiconductor device according to an embodiment 5 of the present invention;

FIG. 10 is a schematic sectional view showing a mount body of an electronic device according to an embodiment 6 of the present invention;

FIG. 11 is a schematic sectional view showing a mount body of a semiconductor device according to an embodiment 7 of the present invention;

FIG. 12 is a schematic sectional view showing a structure of a mount body of a semiconductor device to be implemented by the present invention; and

FIG. 13 is a schematic sectional view showing a basic structure of amount body of an electronic device to be implemented by the present invention.

### DETAILED DESCRIPTION OF THE INVENTION

Hereinafter, preferred embodiments of the present invention are described in detail with reference to the drawings.

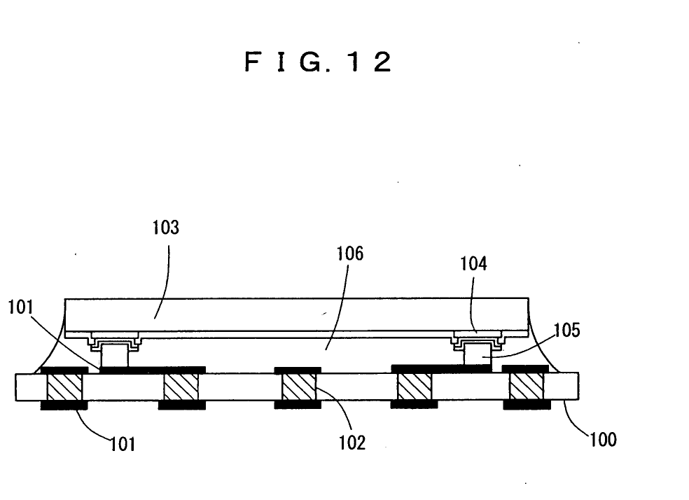

Referring to FIG. 12, a description is made of a structure in which a semiconductor device is mounted on a circuit substrate. Reference numeral 100 designates a circuit substrate, reference numeral 101 designates a terminal electrode of the circuit substrate 100, reference numeral 102 designates a via hole, reference numeral 103 designates a semiconductor device, reference numeral 104 designates an electrode pad of the semiconductor device 103, reference numeral 105 designates a solder bump provided at the electrode pad 104 to constitute the terminal electrode, and reference numeral 106 designates a sealing resin.

According to a mounting structure shown in FIG. 12, the solder bump 105 is previously formed at the electrode pad 104 of the semiconductor device 103 before the semiconductor device 103 is connected to the circuit substrate 100. After the solder bump 105 is formed, the semiconductor device 103 is arranged face down on the circuit substrate 100. In this state, the solder bump 105 is heated up to high temperature and fusion bonded to the terminal electrode 101 of the circuit substrate 100. This structure has strong mechanical strength in the connection between the electrode pad 104 and the terminal electrode 101, and the electrode pad 104 can be connected to the terminal electrode 101 at once.

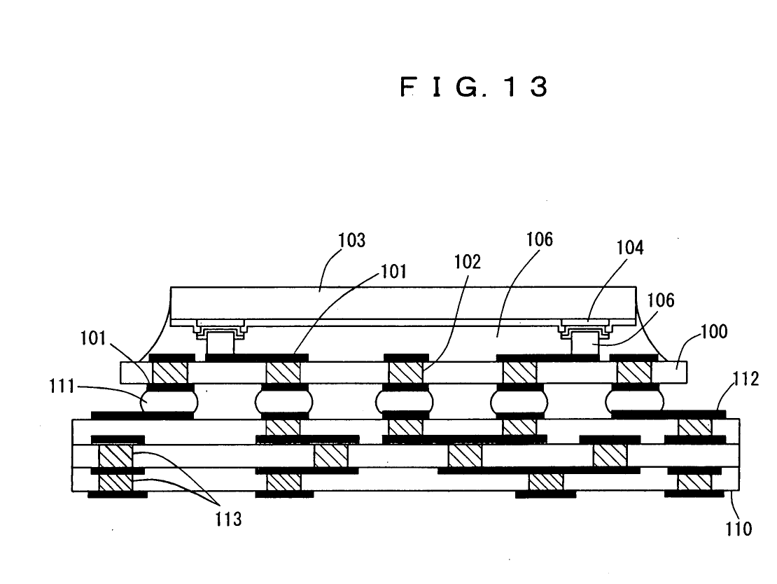

FIG. 13 shows a structure in which the mounting structure shown in FIG. 12 is mounted on a mother circuit substrate.

Referring to FIG. 13, reference numeral 110 designates a mother circuit substrate, reference numeral 111 designates a solder connection portion, reference numeral 112 designates a terminal electrode of the mother circuit substrate 110, and reference numeral 113 designates a via hole formed in the mother circuit substrate 110.

According to the structure shown in FIG. 13, a solder paste is formed on the terminal electrode 112 by printing or the like. Then, the terminal electrode 112 and the terminal electrode 101 are aligned. In this aligned state, the circuit substrate 100 is mounted on the mother circuit substrate 110. In this state, the solder paste on the terminal electrode 112 is heated up to a melting point or more. Thus, the solder connection portion 111 is formed. The terminal electrode 101 and the terminal electrode 112 are connected by this solder connection portion 111.

When wiring widths of the terminal electrodes 101 and 112 are relatively large, reliability of the connection between the terminal electrodes 101 and 112 is relatively high. However, miniaturization of the semiconductor device requires the wiring widths of the terminal electrodes 101 and 112 to be 15 μm or less. In the structures shown in FIGS. 12 and 13, it is difficult to secure high connection reliability while this request is answered.

Hereinafter, its reason is described.

For example, when the terminal electrodes 101 and 112 are connected through a connection material such as solder or a conductive adhesive, it is necessary to sufficiently ensure an area (referred to as a necessary contact area hereinafter) in which the terminal electrodes 101 and 112 are in contact with the solder (the same applied to another connection material), in order to acquire the high reliability in connection between the terminal electrodes 101 and 112. However, when the wiring width is 15 μm or less, a region (referred to as an actually contactable region hereinafter) in which the terminal electrodes 101 and 112 can be in contact with the solder is inevitably reduced. Therefore, in order to acquire the high connection reliability in the very narrow wiring width, it is necessary to increase the necessary contact area in the actually contactable region to the maximum.

However, several kinds of plating layers are formed on the surface of the terminal electrodes 101 and 112 so as to be well fit to the solder or so as not to be rusted. When the plating layer is formed, minute dents are formed. The minute dents mean minute concavities and convexities or a minute porous configuration on the plating layer. The minute dents prevent the necessary contact area from becoming large.

Meanwhile, even when a method of forming a wiring electrode with minute pitch called an additive process is used, since this method itself forms the surface of the wiring electrode by plating, minute dents are formed on the electrode surface even if the plating layer is not formed on the surface of the terminal electrodes 101 and 112. As a result, similar to the above, it is difficult to enlarge the necessary contact area.

Hereinafter, each embodiment of the present invention in which the problems in the structures shown in FIGS. 12 and 13 are solved is described with reference to the drawings.

(Embodiment 1)

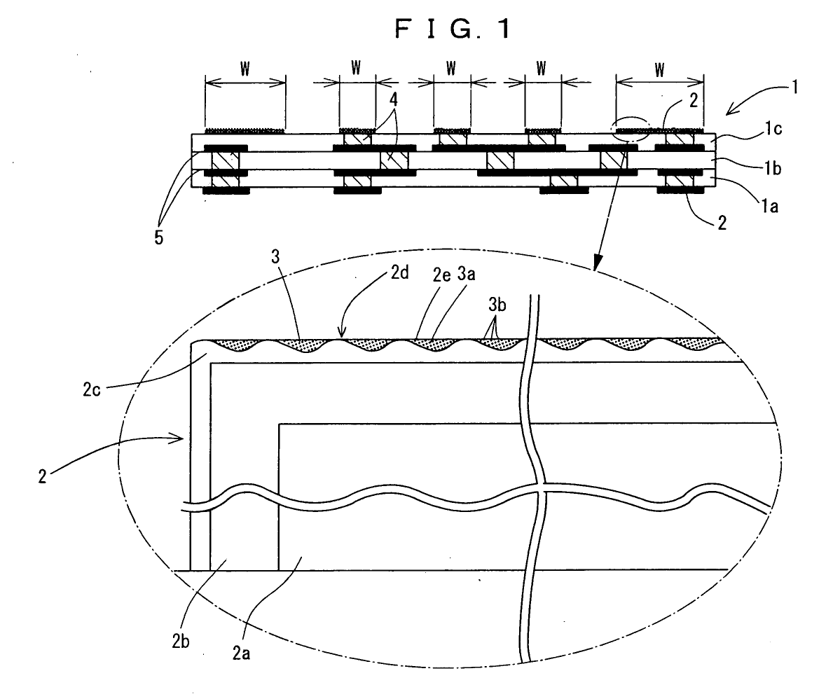

Referring to FIG. 1, a circuit substrate 1 has a structure in which a plurality of insulating substrates 1a, 1b and 1c are laminated. The present invention is not limited to the number of laminated layers of the insulating substrates 1a, 1b and 1c. Internal wiring layers 5 are sandwiched between the insulating substrates 1a, 1b and 1c. The internal wiring layers 5, and the internal wiring layer 5 and the terminal electrode 2 are connected each other through via holes 4. This connection is called interlayer connection.

A part of the terminal electrode 2 is enlarged and shown by a dotted line in which each terminal electrode 2 comprises an internal layer 2a, a middle layer 2b covering the internal layer 2a and a surface layer 2c covering the middle layer 2b. The internal layer 2a is formed of copper foil. The middle layer 2b is formed of a nickel plating layer. The surface layer 2c is formed of a gold plating layer. An electrode width W of the terminal electrode 2 comprising the above constitution is 15 μm or less.

A surface 2d of the surface layer 2c has a rough configuration having minute dents 2e. The minute dents 2e are formed of minute concavities and convexities or a minute porous configuration formed on the surface 2d. The minute dents 2e are formed not only when the surface layer 2c (gold plating layer or the like) is manufactured but also when the surface 2d of the terminal electrode 2 is damaged when the circuit substrate 1 is handled or transported. More specifically, the surface 2d is 1.0 μm to 1.5 μm in surface roughness defined by ten point average height Rz. The ten point average height is the well-known measuring method and it designates a difference between an average value of heights from the top to the fifth height, and an average value of heights from the bottom to the fifth height, in a part where a reference length is extracted from a sectional curve. In addition, the above reference length is appropriately about 2.5 μm to 8.0 μm.

The conductive adhesive 3 is provided on the surface 2d of the surface layer 2c serving as the surface of the terminal electrode 2. The conductive adhesive 3 is made by mixing a resin binder 3a and conductive particles 3b. The resin binder 3a is formed of a ultraviolet cure resin or a thermoplastic resin. The conductive particles 3b are formed of a metal filler such as a silver filler, for example. The conductive particle 3b has a size so as to get in the minute dent 2e. More specifically, a particle diameter of the conductive particle 3b is set so that it can get in the minute dent 2e on the surface 2d having surface roughness of 1.0 μm to 1.5 μm which is defined by the ten point average height Rz. That is, an average particle diameter of the conductive particle 3b is set at 0.001 μm (1 nm) to 0.3 μm (300 nm) which is smaller than the surface roughness of the surface 2d. Thus, the conductive particles 3b get in the minute dent 2e.

When the conductive adhesive 3 gets in the minute dents 2e, the surface 2d becomes smooth. More specifically, the surface 2d becomes a smooth surface of 0.001 μm (1 nm) to 0.3 μm (300 nm) in terms of the ten point average height. Thus, the surface 2d is constituted so as to have the smooth surface by selectively filling only the minute dents 2e with the conductive adhesive 3. Such structure can be formed as follows, for example.

The undried or uncured conductive adhesive 3 is applied on the surface layer 2c by spin coating and then the conductive adhesive 3 is dried or cured. Then, the conductive adhesive 3 is polished until the top of the surface 2d is exposed. Thus, the conductive adhesive 3 can be selectively formed only in the minute dents 2e.

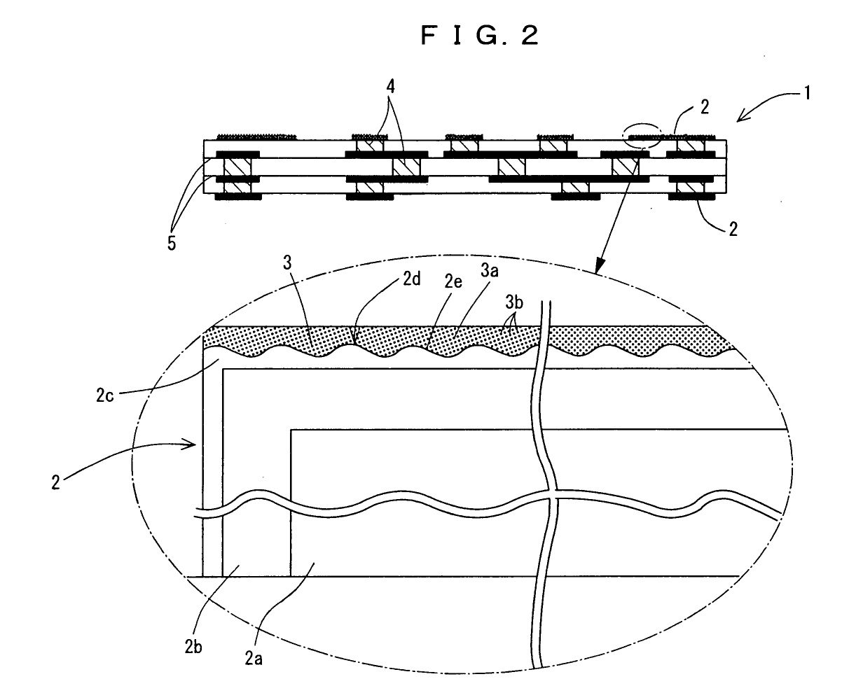

In addition, as shown in FIG. 2, the conductive adhesive 3 may be provided so as to cover the surface layer 2c. In this case, the undried or uncured conductive adhesive 3 is applied on the surface layer 2c by spin coating and then dried and cured. In this case also, the surface of the conductive adhesive 3 becomes a smooth surface of 0.001 μm (1 nm) to 0.3 μm (300 nm) in terms of the ten point average height. In addition, in this case, it is needless to say that the surface of the conductive adhesive 3 may be polished so as to further smooth the surface of the conductive adhesive 3.

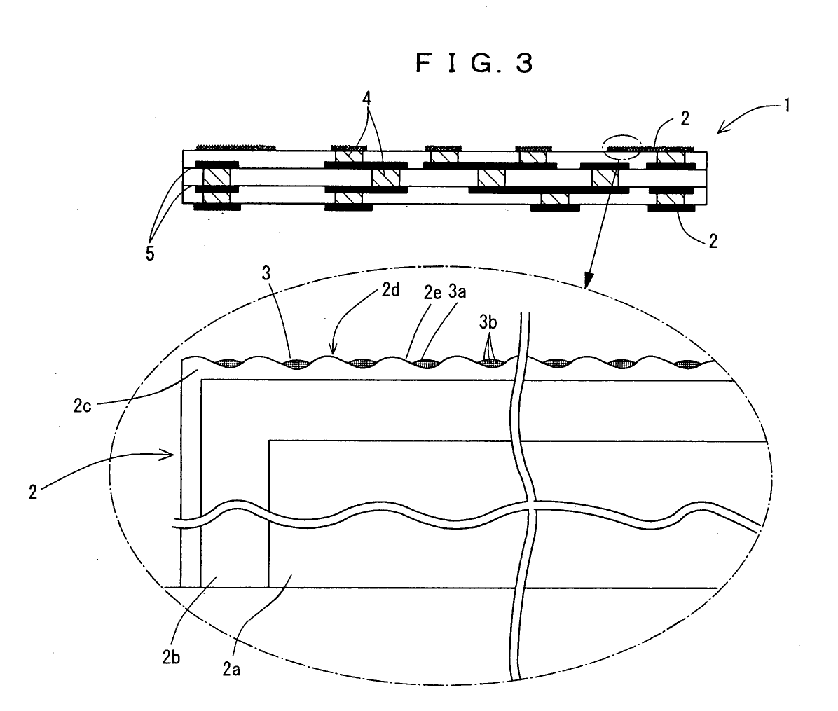

Furthermore, as shown in FIG. 3, only a part of the minute dent 2e may be filled with the conductive adhesive 3 instead of filling the whole of the minute dent 2e. In this case, since the minute dent 2e is not completely filled with the conductive adhesive 3, the surface 2d does not become sufficiently smooth.

As the method of forming the conductive adhesive 3, it may be a jet printing method instead of the spin coating.

When the conductive adhesive 3 is formed as described above, the conductive particles 3b of the conductive adhesive 3 get in the minute dent 2e on the surface 2d of the terminal electrode 2. Therefore, since the minute dents 2e are filled with the conductive adhesive 3 containing the conductive particles 3b, the surface 2d becomes smooth. Thus, when a mounting device such as a semiconductor device is mounted on the circuit substrate 1 to be electrically connected, its connection reliability between the circuit substrate 1 and the mounting device can be improved. This is because the minute dents 2e are filled with the conductive adhesive 3 and become smooth, so that a contact area between the terminal electrode of the mounting device and the terminal electrode 2 of the circuit substrate 1 is enlarged.

In addition, the smoothness of the minute dents 2e is not sufficient in the constitution shown in FIG. 3. In the case of the constitution shown in FIG. 3, an external connection portion of the mounting device is pressure welded to the terminal electrode 2 until the minute dents 2e are crushed to some extent. Thus, the connection reliability between the circuit substrate 1 and the mounting device is improved. This is because the conductive particles 3b of the conductive adhesive 3 engage in the surface 2d of the terminal electrode 2 and the external connection portion of the mounting device. The reason for the above is described in detail as follows. First, the engagement increases the contact area between the external connection portion of the mounting device and the terminal electrode 2 of the circuit substrate 1. Second, the above engagement secures the contact between the external connection portion and the terminal electrode 2. Third, the above engagement shortens the connection distance between the external connection portion and the terminal electrode 2.

In addition, the conductive adhesive 3 comprises the resin binder 3a formed of the ultraviolet cure resin or the thermoplastic resin, and the conductive particles 3b engage in the surface of the minute dents 2e because of shrinkage generated when the resin binder 3a is cured or dried. Therefore, the conductive particles 3b can be further surely electrically connected to the terminal electrode 2. Thus, the connection reliability between the circuit substrate 1 and the mounting device is further enhanced.

Furthermore, when the conductive particles 3b engage in the surface of the minute dents 2e, the connection distance between the mounting device and circuit substrate 1 through the conductive particles 3b is further shortened. As a result, the connection reliability between the circuit substrate 1 and the mounting device can be further improved. The effect of the short connection distance can be obtained also when the mounting device is pressure welded to the terminal electrode 2 in the constitution shown in FIG. 3.

Still further, stress generated between the circuit substrate 1 and the mounting device can be released by providing the conductive adhesive 3 in the minute dents 2e of the terminal electrode 2. Therefore, even when stress such as thermal stress is generated between the circuit substrate 1 and the mounting device due to a secular change of the mounting device and the circuit substrate 1 after the mounting device is mounted on the circuit substrate 1, the stress can be effectively absorbed by the conductive adhesive 3 provided in the minute dents 2e. Therefore, the reliability of the electrical connection between the circuit substrate 1 and the mounting device is prevented from deteriorating due to stress through aging.

The conductive particle 3b is constituted such that, other than silver (Ag), at least one of carbon (C), nickel (Ni), copper (Cu), cobalt (Co), lead (Pb), iron (Fe), Platinum (Pt), gold (Au), indium (In) and tin (Sn) becomes a major element and one or more kinds of the above elements may be mixed to the major element, or an alloy of two or more kinds of the above elements may be mixed to the major element. Still further, the conductive particles 3b may be coated with plating.

The conductive adhesive 3 may include an ion capture or sacrificial conductive particles. The sacrificial conductive particles are selected from one having ion inclination higher than the following metal group. The metal group is formed of copper (Cu), tin (Sn), nickel (Ni), cobalt (Co), iron (Fe), Chrome (Cr), zinc (Zn), manganese (Mn), aluminum (Al), magnesium (Mg) and calcium (Ca).

The resin binder 3a constituting the conductive adhesive 3 may be a thermosetting resin other than the ultraviolet cure resin and the thermoplastic resin. More specifically, there are an epoxy resin, a polyallyl ether resin, a polyamide resin, a polyester resin, a polyimide resin and the like as appropriate resin materials.

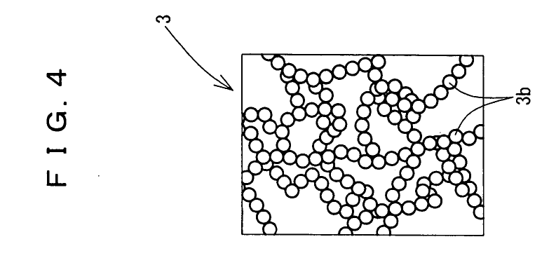

The configuration of the conductive particle 3b may be a spherical shape, a chain shape or a flake shape. As shown in FIG. 4, the chain shape means a state in which the conductive particles 3b are connected in the shape of chain. The chain-shaped conductive particles 3b has a characteristic in which electrical conductivity can be generated with less number of particles (the number of fillings) because they can be easily attached to each other. Such characteristic is noticeable in the chain-shaped conductive particles 3b having magnetism such as nickel.

Although the surface roughness of the terminal electrode body 2a is about 1.0 μm to 1.5 μm in terms of the ten point average height, when the middle layer 2b is formed by plating so as to be about 3 μm in thickness and the surface layer 2c is formed by plating so as to be about 0.05 μm to 0.5 μm in thickness, a metal bump is formed on the surface 2d of the surface layer 2c because of plating precipitation. Therefore, the minute dents 2e each having a size of several 100 nm to several μm are formed at the intervals of several μm to 10 μm. In addition, when the circuit substrate 1 is handled at the time of transportation or the like, the surface layer 2c could be damaged and the surface layer 2c could be partially cut out so that the middle layer 2b is exposed. In this case, concavities and convexities of 0.3 μm or more are partially formed. Furthermore, minute porous configuration of about several 10 nm to several 100 nm could be generated on the surface 2d because of pinholes generated when the surface layer 2c or the like is formed by plating. Thus, the surface 2d has the surface roughness of about 1.0 μm to 1.5 μm as defined by the ten point average height Rz because of the several kinds of minute dents 2e generated in the surface layer 2c.

Since the conductive particle 3b has a very small particle diameter, its particle size distribution is very sharp. For example, in the case of the conductive particle 3b having an average particle diameter of 50 nm, the particle size distribution is within ±5%. A specific surface area of the conductive particle 3b is appropriately about 2 m2/g to 90 m2/g. In addition, a bulk density of the conductive particle 3b is appropriately about 0.1 g/cc to 3 g/cc. A content of the conductive particle 3b in the conductive adhesive 3 is appropriately 12 Vol % to 98 Vol %. In addition, an ion trap agent may be mixed in the conductive adhesive 3. When the ion trap agent is mixed, in a case where a water solution including halogen impurity ion such as bromine (Br), chlorine (Cl) or the like enters the conductive adhesive 3 while left unattended in the damp or biased in the damp, anion can be captured by the ion trap agent. The ion trap agent is in organic hydrotalcite and its content is preferably about 0.1 wt % to 15 wt %. More preferably, it is about 0.01 wt % to 10 wt %. A particle diameter of the ion trap agent is preferably small in order to increase ion capturing speed and increase a contact with an intended capture ion exchanger. More specifically, an average particle diameter of the ion trap agent is 1 μm or less and more preferably several nm to several 100 nm.

In order to maintain a preferable printing property of the conductive adhesive, a viscosity of the undried or uncured conductive adhesive 3 is preferably about 2 Pa·s to 100 Pa·s. A solvent may be contained in the conductive adhesive 3.

(Embodiment 2)

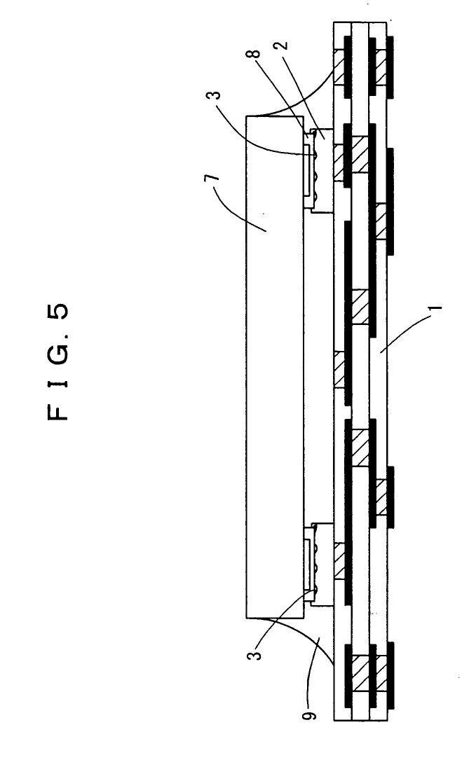

FIG. 5 is a schematic sectional view of mounting devices of a semiconductor device according to an embodiment 2 of the present invention. Referring to FIG. 5, reference numeral 7 designates a semiconductor device, and reference numeral 8 designates a terminal electrode of the semiconductor device. According to this embodiment, a mounting device is the semiconductor device 7 and an external connection portion of the mounting device is the terminal electrode 8.

According to this embodiment, the semiconductor device 7 is mounted face down on a circuit substrate 1 of the embodiment 1. Thus, the terminal electrode 8 of the semiconductor device 7 is pressure welded or fusion bonded to the terminal electrode 2 of the circuit substrate 1 through a conductive adhesive engaged between them. Here, the fusion bonding includes a state in which a part of the terminal electrode 8 and a part of the terminal electrode 2 are fusion bonded together. In addition, the pressure welding includes a pressed state in which minute dents 2e are not crushed and a pressed state in which the minute dents 2e are crushed.

Thus, the terminal electrode 8 of the semiconductor device 7 is electrically connected to the terminal electrode 2 of the circuit substrate 1. Thus, connection reliability thereof is improved.

The semiconductor device 7 according to this embodiment corresponds to the mounting device of the embodiment 1. The detailed reason why the connection reliability of the structure of this embodiment is high is basically the same as that when the mounting device is mounted on the circuit substrate 1 according to the embodiment 1. This embodiment implements the present invention in the structure in which the semiconductor device 7 which is the mounting device is mounted face down on the circuit substrate 1.

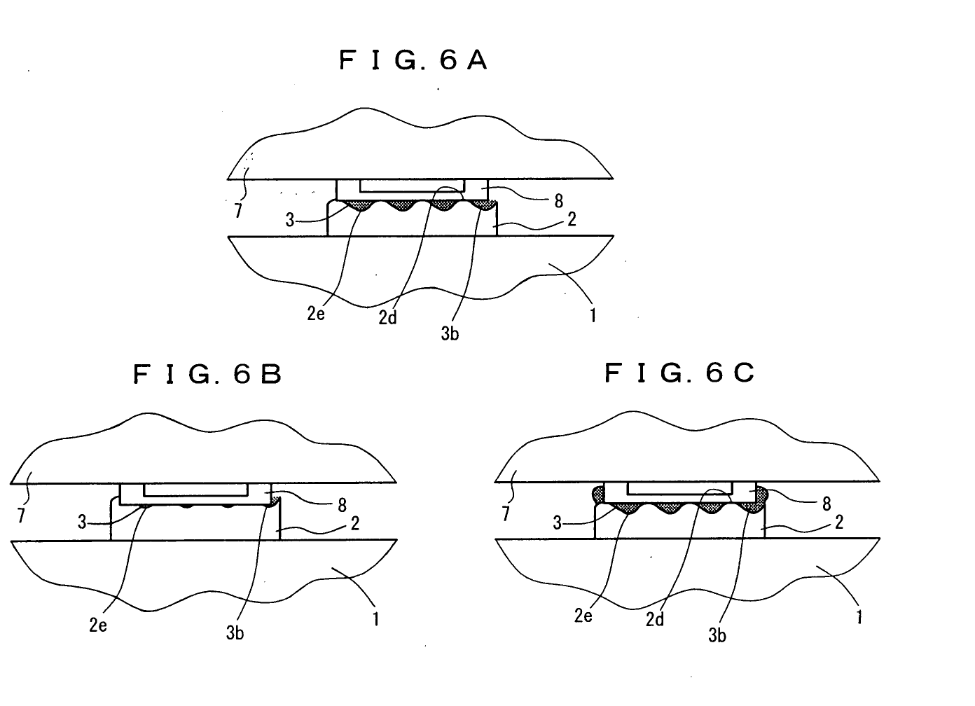

According to this embodiment, there are the following three constitutions as the constitution in which the semiconductor device 7 is mounted on the circuit substrate 1. According to the first constitution, as shown in FIG. 6A, a surface 2d of the terminal electrode 2 of the circuit substrate 1 is smoothed by filling the minute dents 2e with a conductive adhesive 3, and the terminal electrode 8 of the semiconductor device 7 comes in contact with the smoothed terminal electrode 2. Thus, both electrodes 2 and 8 are pressure welded or fusion bonded together and electrically connected through the conductive adhesive 3. According to the first constitution, the minute dents 2e are not necessarily to be crushed by the terminal electrode 8 at the time of the pressured welding.

According to the first constitution, since a contact area (bonding area) between the terminal electrode 2 and the terminal electrode 8 is enlarged by smoothing the terminal electrode 2, the connection reliability between both electrodes 2 and 8 is improved. The constitution of the circuit substrate 1 required for implementing the first constitution is that of the circuit substrate 1 described in the embodiment 1 with reference to FIGS. 1 and 2.

According to the second constitution, as shown in FIG. 6B, the minute dents 2e of the terminal electrode 2 are filled with the conductive adhesive 3, and the terminal electrode 8 of the semiconductor device 7 comes to contact with the terminal electrode 2 in this state and both electrodes 2 and 8 are pressure welded. At that time, the minute dents 2e of the terminal electrode 2 are crushed and then both electrodes 2 and 8 are pressure welded or fusion bonded to be electrically connected through the conductive adhesive 3. According to the second constitution, since the conductive adhesive 3 engages in the surface of the minute dents 2e, the bonding strength between both electrodes 2 and 8 through the conductive adhesive 3 is increased and a connection distance is shortened. As a result, the connection reliability between both electrodes 2 and 8 is improved. The constitution of the circuit substrate 1 required for implementing the second constitution is that of the circuit substrate 1 described in the embodiment 1 with reference to FIGS. 1 to 3. In addition, according to the second constitution, it is not always needed to fill the whole of the minute dent 2e with the conductive adhesive 3. As shown in FIG. 3, a part of the minute dent 2e may be filled with the conductive adhesive 3. This is because the minute dents 2e are crushed.

According to the third constitution, as shown in FIG. 6C, the surface 2d of the terminal electrode 2 of the circuit substrate 1 is covered with the conductive adhesive 3 having the smoothed surface, and the terminal electrode 8 of the semiconductor device 7 comes into contact with the conductive adhesive 3 in this state. Then, the terminal electrode 8 is pressed and comes into contact with the terminal electrode 2. Thus, the electrodes 2 and 8 are pressure welded or fusion bonded to be electrically connected through the conductive adhesive 3. According to the third constitution, the minute dents 2e are not necessarily to be crushed by the terminal electrode 8 at the time of the pressure welding. Then, in this state, the electrodes 2 and 8 are bonded by the conductive adhesive 3. At this time, the conductive adhesive 3 protrudes to the periphery when the electrodes 2 and 8 are bonded and it is disposed so as to surround the periphery of the connection portion between the electrodes 2 and 8. According to the third constitution, since the terminal electrode 2 is smoothed by the conductive adhesive 3, the contact area (bonding area) between the terminal electrode 2 and the terminal electrode 8 is increased and the connection reliability of both electrodes 2 and 8 is improved. Furthermore, according to the third constitution, since the conductive adhesive 3 is disposed so as to surround the connection portion between the terminal electrode 2 and the terminal electrode 8, the contact area (bonding area) between the terminal electrode 2 and the terminal electrode 8 is further increased, whereby the connection reliability between both electrodes 2 and 8 is further improved. In addition, in this case, the increased contact area means the contact area of both electrodes 2 and 8 through the conductive adhesive 3 surrounding both electrodes 2 and 8.

Since the conductive adhesive 3 has a function of releasing thermal stress generated between both electrodes 2 and 8, when the conductive adhesive 3 is disposed so as to surround both electrodes 2 and 8 like in the third constitution, the thermal stress generated between both electrodes 2 and 8 is further effectively released.

The constitution of the circuit substrate 1 required for implementing the third constitution is that of the circuit substrate 1 described in the embodiment 1 with reference to FIG. 2.

In addition, although the gap between the semiconductor device 7 and the circuit substrate 1 is sealed with the sealing resin 9 in FIG. 5, it may not been sealed with the sealing resin 9.

(Embodiment 3)

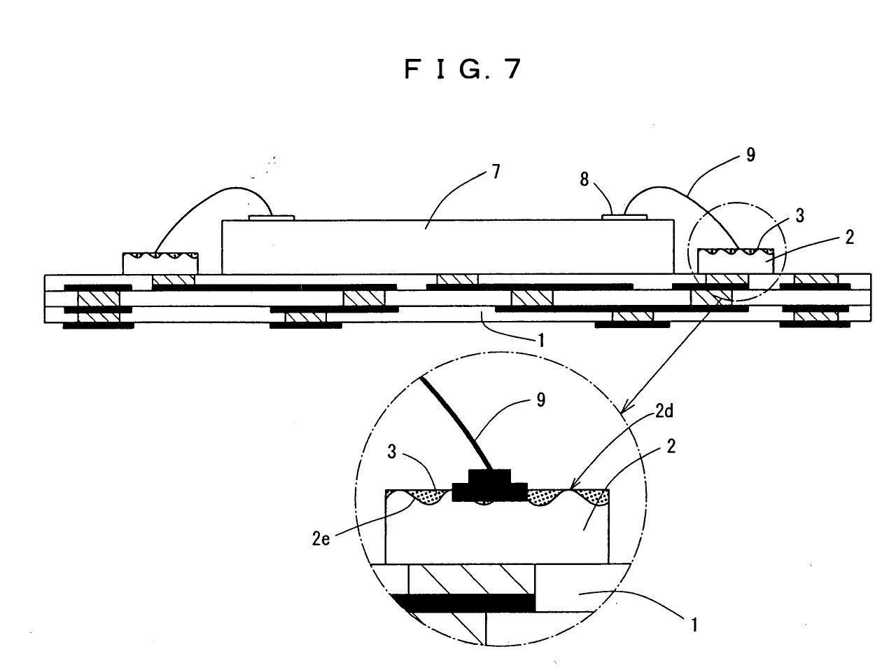

FIG. 7 is a schematic sectional view showing a mount body of a semiconductor device according to an embodiment 3 of the present invention. Referring to FIG. 7, reference numeral 7 designates a semiconductor device, reference numeral 8 designates a terminal electrode of the semiconductor device 7, and reference numeral 9 designates a connection wire formed of a metal line. According to this embodiment, a mounting device is the semiconductor device 7 and an external connection portion of the mounting device is an end portion of the connection wire 9 on the side of the circuit substrate.

The semiconductor device 7 is mounted on a circuit substrate 1 face up. The end of the connection wire 9 connected to the terminal electrode 8 of the semiconductor device 7 is pressure welded or fusion bonded to a terminal electrode 2 of the circuit substrate 1 through a conductive adhesive 3 engaging therein. Here, the fusion bonding includes that a part of the connection wire 9 is fusion bonded to the terminal electrode 2. The pressure welding includes a state in which the minute dents 2e are not crushed and a state in which the minute dents 2e are crushed. The minute dents are crushed in FIG. 7.

Thus, the terminal electrode 8 of the semiconductor device 7 and the terminal electrode 2 of the circuit substrate 1 are bonded and electrically connected. In this state, their connection reliability is improved. In addition, the semiconductor device 7 may be sealed.

The semiconductor device 7 according to this embodiment corresponds to the mounting device in the embodiment 1. Therefore, the detailed reason why the connection reliability of the structure of this embodiment is high is basically the same as that when the mounting device is mounted on the circuit substrate 1 according to the embodiment 1. This embodiment implements the present invention in the structure in which the semiconductor device 7 which is the mounting device is mounted on the circuit substrate 1 by wire bonding. In addition, according to this embodiment, the terminal electrode 8 of the semiconductor device 7 does not come into contact with the terminal electrode 2 of the circuit substrate 1, but the connection wire 9 electrically connected to the terminal electrode 8 is electrically connected to the terminal electrode 2. Therefore, the end of the connection wire 9 on the side of the circuit substrate functions as the terminal electrode of the mounting device. A connection structure between the connection wire 9 and the terminal electrode 2 can employ the same structure as that described in the embodiment 2 with reference to FIGS. 6A, 6B and 6C.

In the embodiments 2 and 3, a projection electrode may be formed on the terminal electrode 8 of the semiconductor device 7. The projection electrode can be formed by a ball bonding method and a plating method. The configuration of the projection electrode formed by the ball bonding may be a pull-off bump, a loop bump or a two-level bump which is provided by forming the above two bumps and leveling them off. In addition, bumps having various kinds of configurations can be formed by the plating method. In addition, a material of the projection electrode may be one of gold (Au), platinum (Pt), silver (Ag), copper (Cu), nickel (Ni), lead (Pb), tin (Sn), bismuth (Bi) and zinc (Zn) or an alloy of them.

In addition, an electrode for LGA or BGA is formed by being patterned into the shape of a lattice area, on a back surface of the circuit substrate 1.

(Embodiment 4)

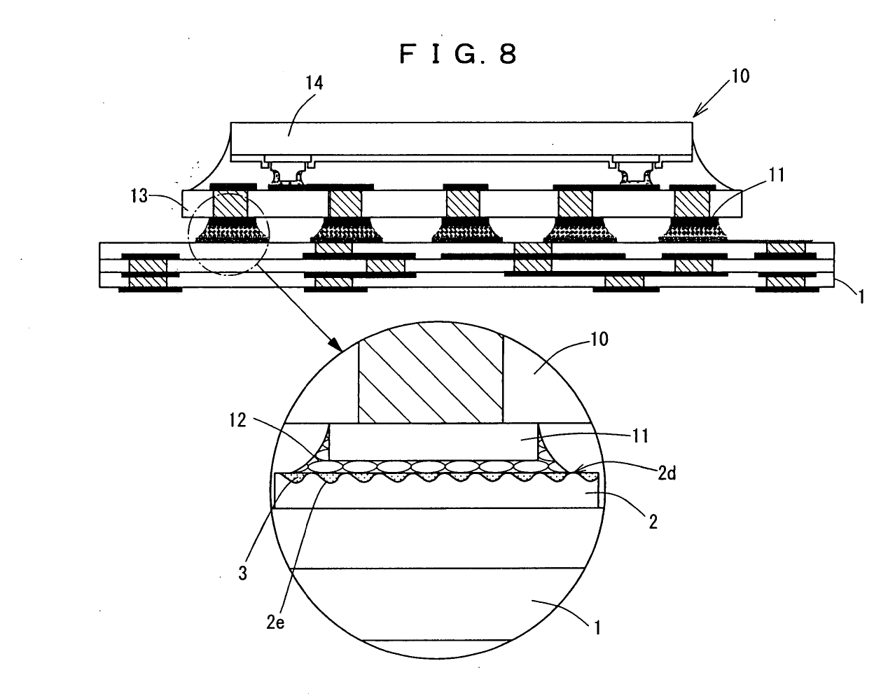

FIG. 8 is a schematic sectional view showing a mount body of an electronic device according to an embodiment 4. Referring to FIG. 8, reference numeral 10 designates an electronic device, reference numeral 11 designates a terminal electrode of the electronic device 10 and reference numeral 12 designates a conductive adhesive. Here, the electronic device 10 is constituted such that a semiconductor device 14 is mounted on a circuit substrate (an interposer substrate) 1. This embodiment is characterized in that another conductive adhesive 12 is provided other than a conductive adhesive 3. According to this embodiment, the mounting device is the electronic device 10 and an external connection portion of the mounting device is the terminal electrode 11.

According to this embodiment, the electronic device 10 is mounted on the circuit substrate (mother circuit substrate) 1 using another conductive adhesive 12. The terminal electrode 11 of the electronic device 10 and the terminal electrode 2 of the circuit substrate 1 are in contact with each other through the conductive adhesive 3 and the conductive adhesive 12, and the terminal electrode 2 of the circuit substrate 1 and the conductive adhesive 3 are strongly connected because the conductive adhesive 3 engages in minute dents 2e and pressure welded or fusion bonded to a surface 2d of the terminal electrode 2. Here, the fusion bonding includes a state in which a part of the conductive adhesive 3 is fusion bonded to the surface 2d. In addition, the pressure welding includes a pressed state in which the minute dents 2e are not crushed and a pressed state in which the minute dents 2e are crushed. Thus, the strongly connected conductive adhesive 3 and the terminal electrode 2 are electrically connected to the terminal electrode 11 through the other conductive adhesive 12.

At this time, the surface 2d of the terminal electrode 2 is smoothed because the minute dents 2e are filled with the conductive adhesive 3, so that a contact area between the terminal electrode 2 and the other conductive adhesive 12 is large. Therefore, the terminal electrode 2 and the other conductive adhesive 12 are strongly bonded to be electrically connected. As a result, the connection reliability between the terminal electrode 2 and the terminal electrode 11 is improved.

The electronic device 10 according to this embodiment corresponds to the mounting device in the embodiment 1. Therefore, the detailed reason why the connection reliability of the structure of this embodiment is high is basically the same as that when the mounting device is mounted on the circuit substrate 1 according to the embodiment 1. This embodiment implements the present invention in the structure in which the semiconductor device 7 which is the mounting device is mounted face down on the circuit substrate 1. The connection structure between the terminal electrode 11 and the terminal electrode 2 can employ the same structure as that described in the embodiment 2 with reference to FIGS. 6A, 6B and 6C. However, the constitution of this embodiment is different from that shown in FIGS. 6A, 6B and 6C in that the other conductive adhesive 12 is provided.

This embodiment is characterized in that the constitution of the other conductive adhesive 12 is different from that of the conductive adhesive 3. According to the conductive adhesive 3, an average particle diameter of a conductive particle 3b is set at 0.001 μm (1 nm) to 0.3 μm (300 nm). Meanwhile, an average particle diameter of each of conductive particles constituting the other conductive adhesive 12 is 5 μm to 20 μm, which is considerably larger than that of the conductive particle 3b. Since the other conductive adhesive 12 having the conductive particles each having too large particle diameters, the minute dents 2e are not filled with those particles. Thus, since the minute dents 2e of the surface layer 2c cannot be filled with the other conductive adhesive 12, the surface layer 2c cannot be smoothed with the conductive adhesive 12 only. The surface layer 2c is not smoothed until the minute dents 2e of the surface layer 2c are filled with the conductive adhesive 3 of this embodiment.

(Embodiment 5)

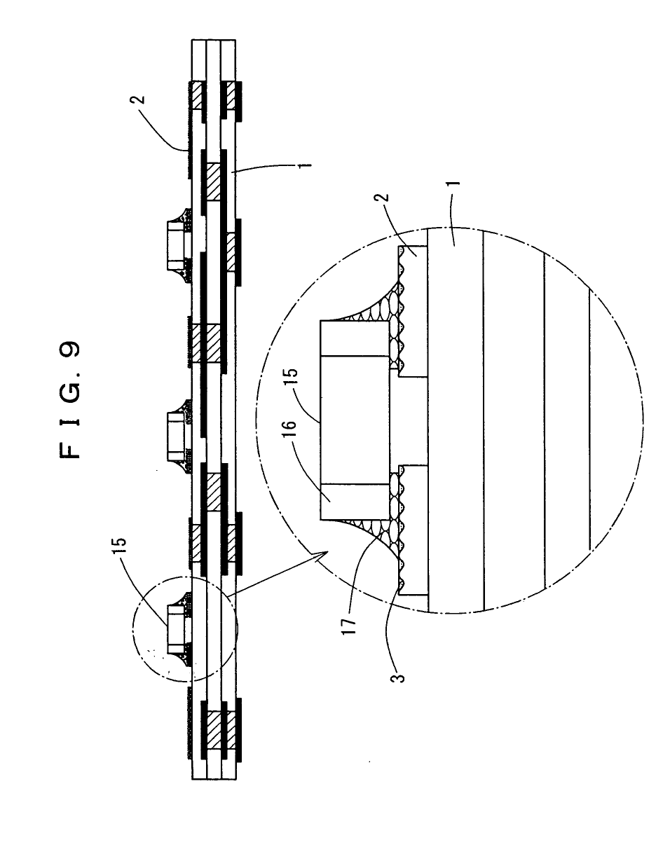

FIG. 9 is a schematic sectional view showing a mount body of an electronic device according to an embodiment 5. Referring to FIG. 9, reference numeral 15 designates an electronic device, reference numeral 16 designates a terminal electrode of the electronic device 15 and reference numeral 17 designates a conductive adhesive. Here, as the electronic device 15, a surface-mounted electronic device such as a chip resistor is used. This embodiment is characterized in that the conductive adhesive 17 is provided other than a conductive adhesive 3. According to this embodiment, the mounting device is the electronic device 15 and an external connection portion of the mounting device is the terminal electrode 16.

According to this embodiment, the electronic device 15 is mounted on a circuit substrate 1 using the other conductive adhesive 17. The terminal electrode 16 of the electronic device 15 and the terminal electrode 2 of the circuit substrate 1 are in contact with each other through the conductive adhesive 3 and the conductive adhesive 17, and the terminal electrode 2 of the circuit substrate 1 and the conductive adhesive 3 are strongly connected electrically because the conductive adhesive 3 engages in minute dents 2e and pressure welded or fusion bonded to a surface 2d of the terminal electrode 2. Here, the fusion bonding includes a state in which a part of the conductive adhesive 3 is fusion bonded to the surface 2d. In addition, the pressure welding includes a pressed state in which the minute dents 2e are not crushed and a pressed state in which the minute dents 2e are crushed.

Thus, the strongly connected terminal electrode 2 and conductive adhesive 3 are electrically connected to the terminal electrode 16 through the other conductive adhesive 17.

At this time, the surface 2d of the terminal electrode 2 is smoothed because the minute dents 2e are filled with the conductive adhesive 3, so that a contact area between the terminal electrode 2 and the other conductive adhesive 17 is large. Therefore, the terminal electrode 2 and the other conductive adhesive 17 are strongly bonded to be electrically connected. As a result, the connection reliability between the terminal electrode 2 and the terminal electrode 16 is improved.

The electronic device 15 according to this embodiment corresponds to the mounting device in the embodiment 1. Therefore, the detailed reason why the connection reliability of the structure of this embodiment is high is basically the same as that when the mounting device is mounted on the circuit substrate 1 according to the embodiment 1. This embodiment implements the present invention in the structure in which the surface-mounted electronic device which is the mounting device is surface-mounted on the circuit substrate 1. The connection structure between the terminal electrode 16 and the terminal electrode 2 can employ the same structure as that described in the embodiment 2 with reference to FIGS. 6A, 6B and 6C. However, the constitution of this embodiment is different from that shown in FIGS. 6A, 6B and 6C in that the other conductive adhesive 17 is provided.

Similar to the embodiment 4, this embodiment is characterized in that the constitution of the other conductive adhesive 17 is different from that of the conductive adhesive 3. According to the conductive adhesive 3, an average particle diameter of a conductive particle 3b is set at 0.001 μm (1 nm) to 0.3 μm (300 nm). Meanwhile, an average particle diameter of each of conductive particles constituting the other conductive adhesive 17 is 5 μm to 20 μm, which is considerably larger than that of the conductive particle 3b. Since the other conductive adhesive 17 having the conductive particles each having too large particle diameters, the minute dents 2e are not filled with those particles. Thus, since the minute dents 2e of the surface layer 2c cannot be filled with the other conductive adhesive 17, the surface layer 2c is not smoothed with the conductive adhesive 12 only. The surface layer 2c is not smoothed until the minute dents 2e of the surface layer 2c are filled with the conductive adhesive 3 of this embodiment.

(Embodiment 6)

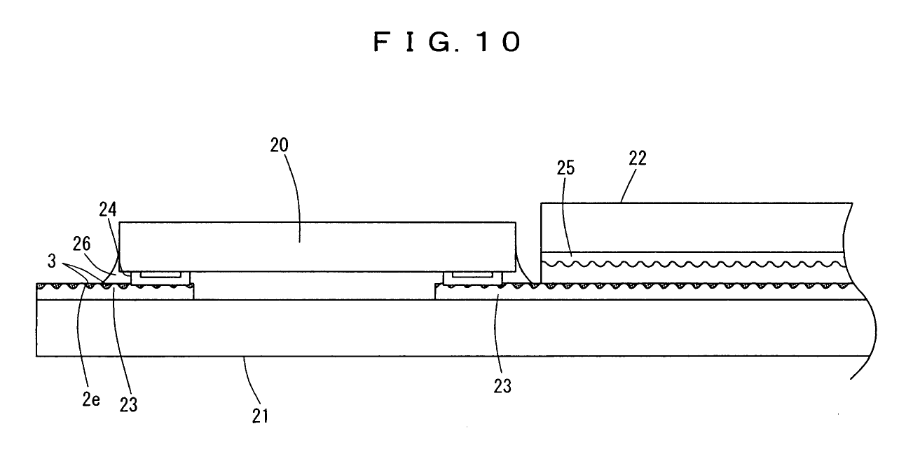

FIG. 10 is a schematic sectional view showing a display according to an embodiment 6. Referring to FIG. 10, reference numeral 20 designates a semiconductor device, reference numeral 21 designates a circuit substrate having the same constitution as that of the circuit substrate 1 of the embodiment 1, reference numeral 22 designates a display, reference numeral 23 designates a terminal electrode of the circuit substrate 21, reference numeral 24 designates a terminal electrode of the semiconductor device 20, and reference numeral 25 designates a terminal electrode of the display 22. According to this embodiment, a mounting device is the semiconductor device 20 and an external connection portion of the mounting device is the terminal electrode 24.

According to this embodiment, the semiconductor device 20 is mounted face down on the circuit substrate 21 on which the display 22 has been previously mounted. The terminal electrode 24 and the terminal electrode 23 are pressure welded or fusion bonded while a conductive adhesive 3 engages in minute dents 2e on the surface of the terminal electrode 23 of the circuit substrate 21. Here, the fusion bonding includes that a state in which a part of the terminal electrode 24 and a part of the terminal electrode 23 are fusion bonded to each other. The pressure welding includes a pressed state in which minute dents 2e are not crushed and a pressed state in which the minute dents 2e are crushed.

Thus, the terminal electrode 24 of the semiconductor device 20 and the terminal electrode 23 of the circuit substrate 21 are bonded and electrically connected. As a result, the connection reliability between both electrodes 24 and 23 is improved. In addition, although the gap between the semiconductor device 20 and the circuit substrate 1 is sealed with the sealing resin 26 in FIG. 10, it may not be sealed with the sealing resin 26.

The semiconductor device 20 according to this embodiment corresponds to the mounting device in the embodiment 1. Therefore, the detailed reason why the connection reliability of the structure of this embodiment is high is basically the same as that when the mounting device is mounted on the circuit substrate 1 according to the embodiment 1. This embodiment implements the present invention in the structure where the semiconductor device 20 which is the mounting device is mounted face down on the circuit substrate 21. The connection structure between the terminal electrode 24 and terminal electrode 23 can employ the same structure as that described in the embodiment 2 with reference to FIGS. 6A, 6B and 6C. In addition, as shown in FIGS. 8 and 9, another conductive adhesive may be provided between the terminal electrode 24 and the terminal electrode 23 other than the conductive adhesive 3.

In addition, according to this embodiment, as the circuit substrate 21, a glass substrate or a plastic substrate for a liquid crystal or an organic EL display is appropriately used.

(Embodiment 7)

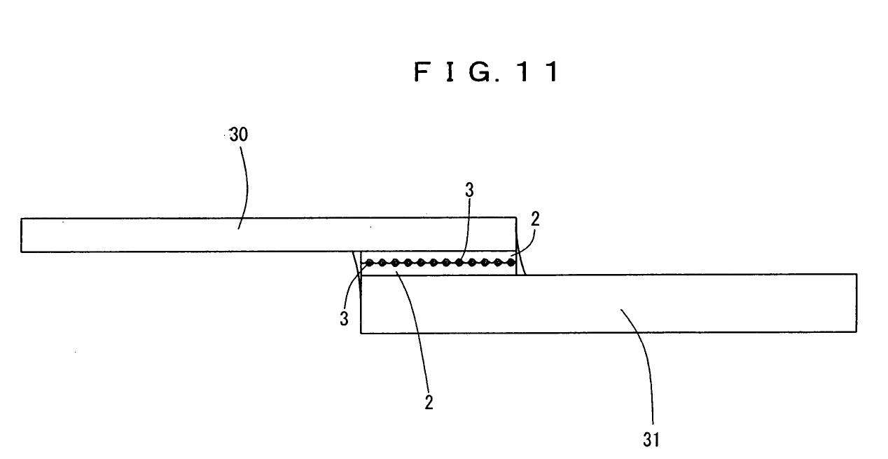

FIG. 11 is a schematic sectional view showing an electronic device according to an embodiment 7 of the present invention. Referring to FIG. 11, reference numerals 30 and 31 designate circuit substrates comprising flexible substrates such as polyimide substrates, liquid crystal polymer substrates or the like. These circuit substrates 30 and 31 basically have the same terminal electrode 2 and the conductive adhesive 3 as those in the embodiment 1. According to this embodiment, one of the circuit substrates 31 and 30 becomes the mounting device to the other one of the circuit substrates 30 and 31. Therefore, an external connection portion of the mounting device is the terminal electrode 2 of the other one of the circuit substrates 31 and 30.

The terminal electrodes 2 of the circuit substrates 30 and 31 having such configuration are pressure welded or fusion bonded through a conductive adhesive 3 engaging therein. Here, the fusion bonding includes a state in which a part of the one terminal electrode 2 is fusion bonded to a part of the other terminal electrode 2. The pressure welding includes a pressed state in which the minute dents 2e are not crushed and a pressed state in which the minute dents 2e are crushed.

Thus, the terminal electrodes 2 are strongly bonded and electrically connected. As a result, the connection reliability between the terminal electrodes 2 becomes high.

In addition, one of the circuit substrates 30 and 31 of this embodiment corresponds to the circuit substrate 1 in the embodiment 1 and the other one of them corresponds to the mounting device. Therefore, the detailed reason why the connection reliability of the structure of this embodiment is high is basically the same as that when the mounting device is mounted on the circuit substrate 1 according to the embodiment 1. This embodiment implements the present invention in the structure in which the circuit substrates are electrically connected. The connection structure between the terminal electrodes 2 can employ the same structure as that described in the embodiment 2 with reference to FIGS. 6A, 6B and 6C. In addition, as shown in FIGS. 8 and 9, another conductive adhesive may be provided between the terminal electrodes 2 other than the conductive adhesive 3.

Although the present invention has been described in detail referring to the preferred embodiments, combination and arrangement of components according to the preferred embodiments can be variously changed within the spirit and scope of the present invention being limited only by the terms of the appended claims.

What is claimed is:

1. A circuit substrate comprising:
a terminal electrode provided on a mounted surface of a substrate and having minute dents on its surface; and
a conductive adhesive provided on a surface of the terminal electrode and having conductive particles, wherein the minute dents are filled with the conductive adhesive, and the conductive particles get into the minute dent.

2. A circuit substrate according to claim 1, wherein the conductive particle has a size so as to get into the minute dent.

3. A circuit substrate according to claim 1, wherein surface roughness of the terminal electrode itself is 1.0 μm to 1.5 μm in terms of a ten point average height.

4. A circuit substrate according to claim 3, wherein an average particle diameter of the conductive particle is 1 nm to 300 nm.

5. A circuit substrate according to claim 1, wherein a part of a volume of the minute dent is filled with the conductive adhesive.

6. A circuit substrate according to claim 1, wherein the minute dent is fully filled with the conductive adhesive and a surface of the terminal electrode is smooth.

7. A circuit substrate according to claim 6, wherein the surface of the terminal electrode having the minute dents filled with the conductive adhesive is a smooth surface of 1 nm to 300 nm in terms of a ten point average height.

8. A circuit substrate according to claim 1, wherein the minute dents are filled with the conductive adhesive and then the surface of the terminal electrode is covered with the conductive adhesive.

9. A circuit substrate according to claim 8, wherein the surface of the conductive adhesive covering the surface of the terminal electrode is smooth.

10. A circuit substrate according to claim 9, wherein the surface of the conductive adhesive covering the terminal electrode is a smooth surface of 1 nm to 300 nm in terms of a ten point average height.

11. A circuit substrate according to claim 1, wherein a width of the terminal electrode is 15 μm or less.

12. A circuit substrate according to claim 1, wherein the conductive adhesive comprises a resin binder formed of one of an ultraviolet cure resin, a thermoplastic resin and a thermosetting resin, and the conductive particles engage in a surface of the minute dents when the resin binder shrinks at the time of curing or drying.

13. A mount body of an electronic device comprising:
a circuit substrate according to claim 1; and
an electronic device having an external connection portion, wherein the external connection portion is bonded to the terminal electrode and then the electronic device is electrically connected to the circuit substrate.

14. Amount body of an electronic device according to claim 13, wherein another conductive adhesive is provided between the external connection portion and the terminal electrode.

15. Amount body of an electronic device according to claim 14, wherein the other conductive adhesive has conductive particles and the conductive particle has a configuration larger than the minute dent.

16. Amount body of an electronic device according to claim 13, wherein the external connection portion is pressure welded to the terminal electrode of the circuit substrate and then the conductive particles engage in the external connection portion and the terminal electrode.

17. Amount body of an electronic device according to claim 13, wherein the conductive adhesive surrounds a periphery of a connection portion between the external connection portion and the terminal electrode while being in contact with the connection portion.

18. Amount body of an electronic device according to claim 13, wherein the electronic device is a semiconductor device having a terminal electrode and mounted face down on the circuit substrate, and
the external connection portion is the terminal electrode of the semiconductor device.

19. Amount body of an electronic device according to claim 13, wherein the electronic device is a semiconductor device having a terminal electrode and mounted face up on the circuit substrate, the terminal electrode of the semiconductor device and the terminal electrode of the circuit substrate are electrically connected by a connection wire, and the external connection portion is the connection wire.

20. Amount body of an electronic device according to claim 13, wherein the electronic device is a surface-mounted electronic device having a terminal electrode, and the external connection portion is the terminal electrode of the electronic device.

21. Amount body of an electronic device according to claim 13, wherein the electronic device is the other circuit substrate having a terminal electrode, and the external connection portion is a terminal electrode of the other circuit substrate.
